(19) United States
(12) Patent Application Publication
(10) Pub. No.: US 2025/0287732 A1
(43) Pub. Date: Sep. 11, 2025

(54) LIGHT EMITTING ELEMENT MANUFACTURING METHOD AND LIGHT EMITTING ELEMENT

(71) Applicant: NICHIA CORPORATION, Anan-shi (JP)

(72) Inventors: Ryota YAMAMOTO, Komatsushima-shi (JP); Akira FUJIOKA, Tokushima-shi (JP); Hirofumi KAWAGUCHI, Tokushima-shi (JP)

(73) Assignee: NICHIA CORPORATION, Anan-shi (JP)

(21) Appl. No.: 19/220,565

(22) Filed: May 28, 2025

Related U.S. Application Data
(63) Continuation of application No. PCT/JP2023/040561, filed on Nov. 10, 2023.

(30) Foreign Application Priority Data
Nov. 30, 2022 (JP) 2022-192110
Oct. 31, 2023 (JP) 2023-186715

(51) Int. Cl. H10H 20/82; H10H 20/01

(52) U.S. Cl. CPC H10H 20/82; H10H 20/019

(57) ABSTRACT

A method of manufacturing a light emitting element includes providing a wafer including a first substrate, a semiconductor structure body, a first electrode, and a second electrode; bonding the second surface side of the semiconductor structure body to a second substrate via a bonding member; subsequently, exposing the first surface of the semiconductor structure body by separating the semiconductor structure body and the first substrate from each other; subsequently, forming a first groove in the semiconductor structure body by removing a portion of the semiconductor structure body, the first groove separating the semiconductor structure body into a plurality of element parts on the second substrate; subsequently, roughening surfaces of the plurality of element parts on the second substrate; and separating the second substrate and the plurality of element parts from each other.

### CROSS-REFERENCE TO RELATED APPLICATION

This is a bypass continuation application of International Application PCT/JP2023/040561, filed on Nov. 10, 2023; the entire contents of which are incorporated herein by reference. This application also claims priority to Japanese Application No. 2022-192110, filed on Nov. 30, 2022, and Japanese Application No. 2023-186715, filed on Oct. 31, 2023. The entire contents of these applications are incorporated herein by reference.

### BACKGROUND

The present disclosure relates to a method of manufacturing a light emitting element and a light emitting element.

A known method of manufacturing a light emitting element includes a step of forming a semiconductor layer on a substrate, a step of bonding the semiconductor layer to another substrate, a step of removing the substrate used to form the semiconductor layer, and a step of roughening a surface of the semiconductor layer exposed by removing the substrate. By roughening the surface of the semiconductor layer, the light extraction efficiency can be increased.

### SUMMARY

One object of certain embodiments of the invention is directed to provide a method of manufacturing a light emitting element and a light emitting element, such that a light emitting element with increased light extraction efficiency can be efficiently manufactured.

According to an aspect of the invention, a method of manufacturing a light emitting element includes: providing a wafer, the wafer including a first substrate, a semiconductor structure body located on the first substrate, the semiconductor structure body including a first semiconductor layer, a second semiconductor layer located farther from the first substrate than the first semiconductor layer is from the first substrate, and an active layer positioned between the first semiconductor layer and the second semiconductor layer, a first electrode located on a second surface of the semiconductor structure body, the second surface being positioned at a side opposite to a first surface of the semiconductor structure body, the first surface being positioned at a first substrate side, the first electrode being electrically connected with the first semiconductor layer, and a second electrode located on the second surface, the second electrode being electrically connected with the second semiconductor layer; bonding a second surface side of the semiconductor structure body to a second substrate via a bonding member; after the bonding of the semiconductor structure body to the second substrate, exposing the first surface of the semiconductor structure body by separating the semiconductor structure body and the first substrate from each other; after the exposing of the first surface of the semiconductor structure body, forming a first groove in the semiconductor structure body by removing a portion of the semiconductor structure body, the first groove separating the semiconductor structure body into a plurality of element parts on the second substrate; after the forming of the first groove in the semiconductor structure body, roughening surfaces of the plurality of element parts on the second substrate; and separating the second substrate and the plurality of element parts from each other.

According to an aspect of the invention, a method of manufacturing a light emitting element includes: providing a wafer, the wafer including a first substrate, a semiconductor structure body located on the first substrate, the semiconductor structure body including a first semiconductor layer, a second semiconductor layer located farther from the first substrate than the first semiconductor layer, and an active layer positioned between the first semiconductor layer and the second semiconductor layer, a first electrode located on a second surface of the semiconductor structure body, the second surface being positioned at a side opposite to a first surface of the semiconductor structure body, the first surface being positioned at a first substrate side, the first electrode being electrically connected with the first semiconductor layer, and a second electrode located on the second surface, the second electrode being electrically connected with the second semiconductor layer; bonding a second surface side of the semiconductor structure body to a second substrate via a bonding member; after the bonding of the semiconductor structure body to the second substrate, exposing the first surface of the semiconductor structure body by separating the semiconductor structure body and the first substrate from each other; after the exposing of the first surface of the semiconductor structure body, roughening the first surface of the semiconductor structure body on the second substrate; after the roughening of the first surface of the semiconductor structure body, forming a first groove in the semiconductor structure body by removing a portion of the semiconductor structure body, the first groove separating the semiconductor structure body into a plurality of element parts on the second substrate; and separating the second substrate and the plurality of element parts from each other.

According to an aspect of the invention, a light emitting element includes a semiconductor structure body including a first semiconductor layer, a second semiconductor layer, an active layer positioned between the first semiconductor layer and the second semiconductor layer, a first surface, the first surface being a surface of the first semiconductor layer positioned at a side opposite to the active layer, a second surface positioned at a side opposite to the first surface, a lateral surface connecting the first surface and the second surface, the second surface including a first region in which a portion of the first semiconductor layer is exposed from under the second semiconductor layer and the active layer, and a second region being a surface of the second semiconductor layer positioned at a side opposite to the active layer; a first electrode electrically connected with the first semiconductor layer at the first region; and a second electrode electrically connected with the second semiconductor layer at the second region, in which the first surface and the lateral surface are rough surfaces, and an area of the second surface is greater than an area of the first surface.

According to certain embodiments of the invention, a method of manufacturing a light emitting element and a light emitting element can be provided in which a light emitting element with increased light extraction efficiency can be efficiently manufactured.

### BRIEF DESCRIPTION OF THE DRAWINGS

FIG. 1 to FIG. 11 are schematic cross-sectional views for describing a step of a method of manufacturing a light emitting element according to a first embodiment;

FIG. 12 is a schematic plan view for describing a step of the method of manufacturing a light emitting element according to the first embodiment;

FIG. 13 to FIG. 16 are schematic cross-sectional views for describing a step of the method of manufacturing a light emitting element according to the first embodiment;

FIG. 17 to FIG. 19 are schematic cross-sectional views for describing a step of a method of manufacturing a light emitting element according to a second embodiment;

FIG. 20 to FIG. 22 are schematic cross-sectional views for describing a first modification of the methods for manufacturing the light emitting elements according to the first and second embodiments;

FIG. 23 and FIG. 24 are schematic cross-sectional views for describing a second modification of the methods for manufacturing the light emitting elements according to the first and second embodiments;

FIG. 25A is a schematic plan view of a light emitting element according to an embodiment; and

FIG. 25B is a schematic cross-sectional view along line XXVB-XXVB of FIG. 25A.

### DETAILED DESCRIPTION

Certain embodiments will now be described with reference to the drawings. Unless specifically stated, the dimensions, materials, shapes, relative arrangements, and the like of the components described in the embodiments are not intended to limit the scope of the invention, and are merely illustrative examples. The sizes, positional relationships, and the like of the members shown in the drawings may be exaggerated for clarity of description. Also, in the following description, the same names and reference numerals indicate the same or similar members, and a repeated detailed description is omitted as appropriate. Also, end views that show only cross sections may be used as cross-sectional views. Also, in cross-sectional views, the cross section of the semiconductor structure part is not marked with hatching for easier viewing of the semiconductor structure part.

In the following description, terms that indicate specific directions or positions (e.g., “up,” “down,” and other terms including such terms) may be used. Such terms, however, are used merely for better understanding of relative directions or positions when referring to the drawings. As long as the relationships are the same, the relative directions or positions according to terms such as “up/above,” “down/below,” etc., used when referring to the drawings may not have the same arrangements in drawings, actual products, and the like outside the disclosure. In the specification, when assuming that there are, for example, two members, the positional relationship expressed as “up (or down)” includes the case where the two members are in contact with each other, and the case in which the two members are not in contact with each other and one of the members is positioned above (or below) the other member. Also, in the specification, unless specifically stated, the expression that a member “covers” an object includes the case where the member is in contact with the object and directly covers the covered object, and the case where the member indirectly covers the covered object without being in contact with the covered object.

### First Embodiment

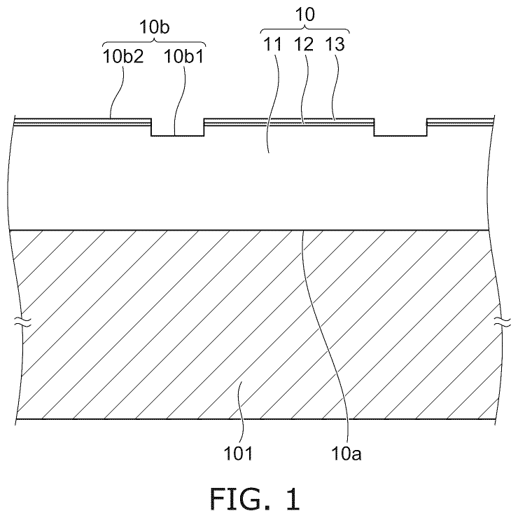

A method of manufacturing a light emitting element according to a first embodiment will be described with reference to FIGS. 1 to 16.

### <Step of Providing Wafer>

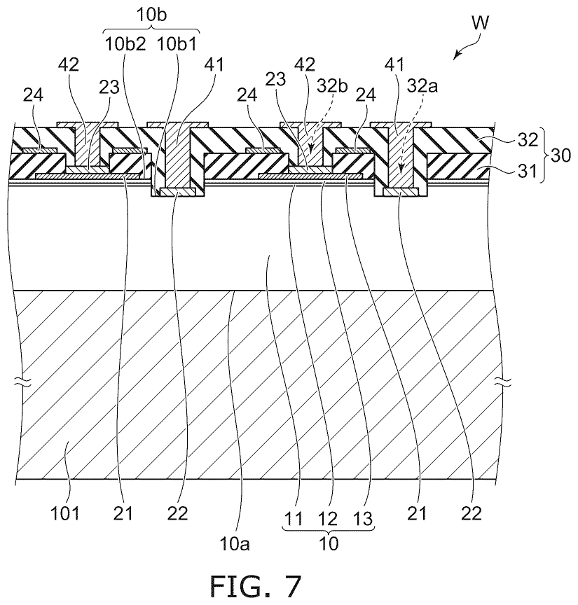

The method of manufacturing a light emitting element according to the first embodiment includes a step of preparing a wafer. FIG. 7 illustrates a portion of a wafer W. The wafer W includes a first substrate 101, a semiconductor structure body 10 located on the first substrate 101, a first electrode 41, and a second electrode 42.

The first substrate 101 can include, for example, an insulating substrate of sapphire or spinel (MgAl₂O₄) having one of a C-plane, an R-plane, or an A-plane as a major surface. Also, a conductive substrate of SiC (including 6H, 4H, and 3C), ZnS, ZnO, GaAs, Si, etc., may be used as the first substrate 101. According to the present embodiment, a sapphire substrate that has a C-plane as a major surface is used as the first substrate 101. The semiconductor structure body 10 is formed on the major surface of the first substrate 101.

The semiconductor structure body 10 is made of a nitride semiconductor. In the specification, “nitride semiconductor” includes, for example, all compositions of semiconductors represented by the chemical formula InₓAl_{y}Ga_{1-x-y}N (0≤x≤1, 0≤y≤1, and x+y≤1) for which the composition ratios x and y are varied within respective ranges respectively. Also, “nitride semiconductor” further includes nitride semiconductors further containing Group V elements other than N (nitrogen) in the chemical formula above, nitride semiconductors further containing various elements added to control various properties such as the conductivity type, etc.

The semiconductor structure body 10 includes a first semiconductor layer 11, a second semiconductor layer 13 located at a position farther from the first substrate 101 than the first semiconductor layer 11, and an active layer 12 positioned between the first semiconductor layer 11 and the second semiconductor layer 13. The active layer 12 is a light emitting layer that emits light, and has, for example, a MQW (Multiple Quantum well) structure including multiple barrier layers and multiple well layers. For example, the active layer 12 emits light having a peak wavelength of not less than 210 nm and not more than 580 nm. For example, the first semiconductor layer 11 includes a semiconductor layer including an n-type impurity, and the second semiconductor layer 13 includes a semiconductor layer including a p-type impurity.

The semiconductor structure body 10 includes a first surface 10a and a second surface 10b. The first surface 10a is positioned at the first substrate 101 side. The second surface 10b is positioned at the side opposite to the first surface 10a. The second surface 10b includes a first region 10b1 and a second region 10b2. In the first region 10b1, a portion of the first semiconductor layer 11 is exposed from the second semiconductor layer 13 and the active layer 12. The surface of the second region 10b2 is the upper surface of the second semiconductor layer 13. The area of the second region 10b2 is greater than the area of the first region 10b1.

The active layer 12 is positioned at the side more proximate to the second region 10b2 of the second surface 10b than the first surface 10a. The thickness of the semiconductor structure body 10 is, for example, not less than 5 μm and not more than 10 μm. For example, the active layer 12 is positioned within the range of not less than 10 nm and not more than 1,000 nm from the second region 10b2 of the second surface 10b.

The first electrode 41 is located on the first region 10b1 of the second surface 10b and is electrically connected with the first semiconductor layer 11. The second electrode 42 is located on the second region 10b2 of the second surface 10b and is electrically connected with the second semiconductor layer 13.

The step of providing the wafer W may include the steps shown in FIGS. 1 to 6. The steps of FIGS. 1 to 6 will now be described. In the step of providing the wafer W, the wafer W shown in FIG. 7 may be provided by purchasing.

In the step shown in FIG. 1, the semiconductor structure body 10 is formed on the first substrate 101. For example, the first semiconductor layer 11, the active layer 12, and the second semiconductor layer 13 are formed in this order on the first substrate 101 by MOCVD (Metal Organic Chemical Vapor Deposition). After the semiconductor structure body 10 is formed on the first substrate 101, a portion of the second semiconductor layer 13 and a portion of the active layer 12 are removed, so that the first region 10b1 and the second region 10b2 are formed in the second surface 10b. For example, the portion of the second semiconductor layer 13 and the portion of the active layer 12 can be removed by dry etching, wet etching, etc.

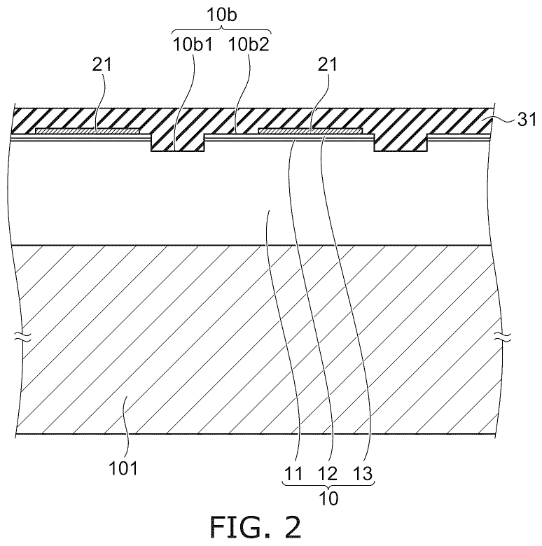

As shown in FIG. 2, the step of providing the wafer W can include forming a first conductive film 21 on the second region 10b2 of the second surface 10b. The first conductive film 21 is in contact with the upper surface of the second semiconductor layer 13 and has the function of diffusing the current supplied via the second electrode 42 in the in-plane direction of the second semiconductor layer 13. For example, a light-transmitting conductive film of ITO (Indium Tin Oxide), IZO (Indium Zinc Oxide), ZnO, In₂O₃, etc., can be used as the first conductive film 21. For example, the first conductive film 21 can be formed by sputtering and/or vapor deposition.

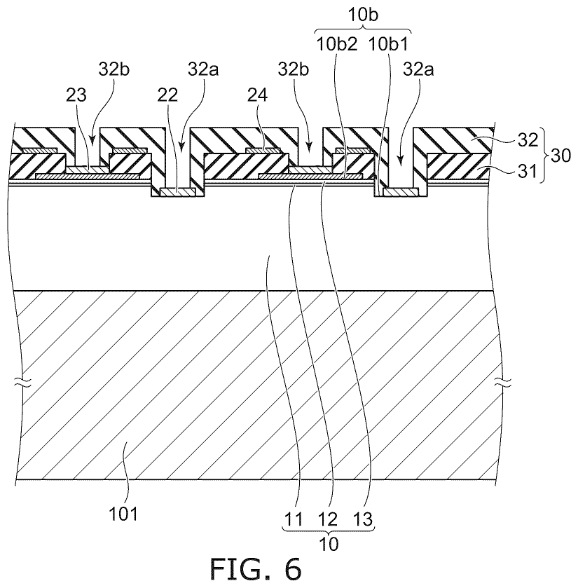

As shown in FIG. 6, the step of providing the wafer W can include forming an insulating film 30, including a first opening 32a and a second opening 32b, at the second surface 10b of the semiconductor structure body 10.

As shown in FIG. 2, the step of forming the insulating film 30 includes forming a first film 31 at the second surface 10b of the semiconductor structure body 10. The first film 31 covers the second surface 10b and the first conductive film 21.

The first film 31 can be a film that is reflective to the light emitted by the active layer 12. The reflectance of the first film 31 for the light emitted by the active layer 12 is not less than 60%, and favorably not less than 70%. The first film 31 includes, for example, a dielectric multilayer film. The dielectric multilayer film includes, for example, a SiO₂ layer and a Nb₂O₅ layer that are alternately stacked. It is favorable to form the first film 31, for example, by forming a relatively thick SiO₂ layer having a thickness of not less than 100 nm and not more than 500 nm, and subsequently forming not less than two and not more than six pairs of a Nb₂O₅ layer having a thickness of not less than 10 nm and not more than 100 nm and a SiO₂ layer having a thickness of not less than 10 nm and not more than 100 nm as a dielectric multilayer film on the relatively thick SiO₂ layer. Setting the film thickness of each layer and the number of stacks of the layers of the first film 31 within these ranges allows for having good light reflectivity. For example, as the first film 31, a SiO₂ layer having a thickness of 300 nm can be formed, and subsequently three pairs of a Nb₂O₅ layer having a thickness of 52 nm and a SiO₂ layer having a thickness of 83 nm can be formed on the SiO₂ layer of the thickness of 300 nm. A material such as titanium oxide (TiO₂), zirconium oxide (ZrO₂), aluminum oxide (Al₂O₃), aluminum nitride (AlN), etc., can be used as the material of the first film 31. For example, the first film 31 can be formed by CVD (Chemical Vapor Deposition) and/or sputtering.

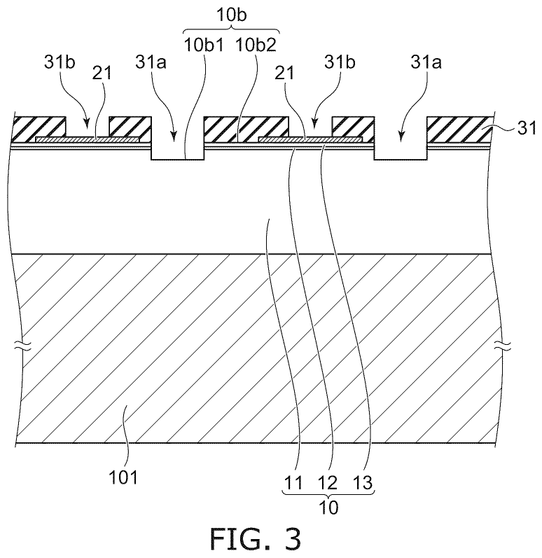

As shown in FIG. 3, the step of forming the insulating film 30 includes forming a fourth opening 31a and a fifth opening 31b in the first film 31. The first region 10b1 of the second surface 10b, i.e., the first semiconductor layer 11, is exposed in the fourth opening 31a of the first film 31. The first conductive film 21 is exposed in the fifth opening 31b of the first film 31. For example, the fourth opening 31a and the fifth opening 31b can be formed by removing portions of the first film 31 by dry etching and/or wet etching.

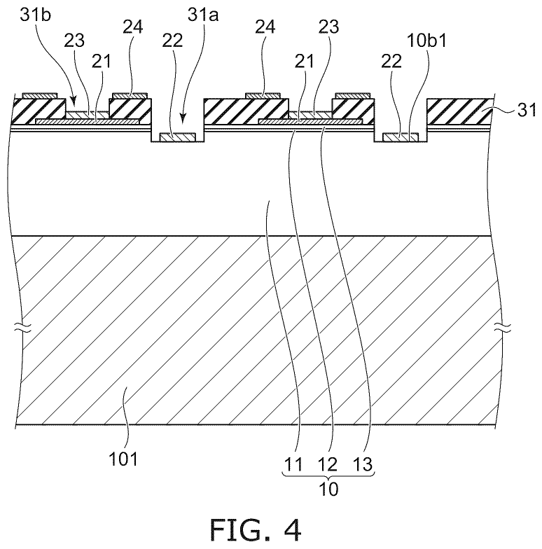

As shown in FIG. 4, the step of preparing the wafer W can include a step of forming a second conductive film 22, a third conductive film 23, and a reflective film 24. For example, the second conductive film 22, the third conductive film 23, and the reflective film 24 can be formed by sputtering and/or vapor deposition.

The second conductive film 22 is located on the first semiconductor layer 11 in the fourth opening 31a, and is electrically connected with the first semiconductor layer 11. The second conductive film 22 allows for reducing the contact resistance between the first electrode 41 and the first semiconductor layer 11.

The third conductive film 23 is located on the first conductive film 21 in the fifth opening 31b, and is electrically connected with the first conductive film 21. The third conductive film 23 allows for reducing the contact resistance between the second electrode 42 and the first conductive film 21.

The second conductive film 22 and the third conductive film 23 can be, for example, a single-layer metal layer including Ti, Rh, Au, Pt, Al, Ag, or Ru, or a stacked structure including at least two among these metal layers. The second conductive film 22 and the third conductive film 23 can be simultaneously formed by using the same material.

The reflective film 24 is formed on the upper surface of the first film 31. The reflective film 24 is reflective to the light emitted by the active layer 12. For example, a metal can be used as the material of the reflective film 24. The reflective film 24 includes, for example, an Al film, a Ti film, or a stacked structure of an Al film and a Ti film.

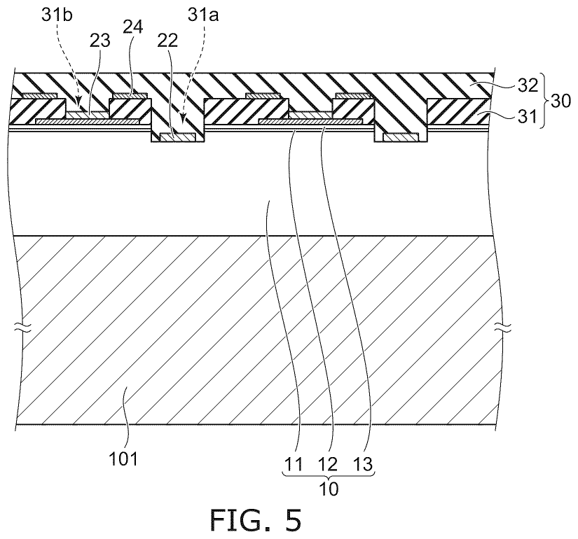

As shown in FIG. 5, the step of forming the insulating film 30 further includes a step of forming a second film 32 on the first film 31. The second film 32 covers the semiconductor structure body 10, the first conductive film 21, the second conductive film 22, the third conductive film 23, and the reflective film 24. For example, SiO₂, SiN, SiON, etc., can be used as the second film 32. For example, the second film 32 can be formed by CVD and/or sputtering.

After the second film 32 is formed, the first opening 32a and the second opening 32b are formed in the second film 32 as shown in FIG. 6. In the first opening 32a, the second conductive film 22 is exposed from under the insulating film 30. In the second opening 32b, the third conductive film 23 is exposed from under the insulating film 30.

As shown in FIG. 7, the first electrode 41 is located in the first opening 32a, and the first electrode 41 is in contact with the second conductive film 22. The first electrode 41 is electrically connected with the first semiconductor layer 11 via the second conductive film 22. The second electrode 42 is located in the second opening 32b, and the second electrode 42 is in contact with the third conductive film 23. The second electrode 42 is electrically connected with the second semiconductor layer 13 via the third and first conductive films 23 and 21. The first electrode 41 and the second electrode 42 include, for example, a Ti layer, a Rh layer, a Au layer, or a stacked structure of any two of the Ti layer, the Rh layer, or the Au layer. The first electrode 41 and the second electrode 42 can be simultaneously formed using the same material. The first electrode 41 and the second electrode 42 can be formed by sputtering and/or vapor deposition.

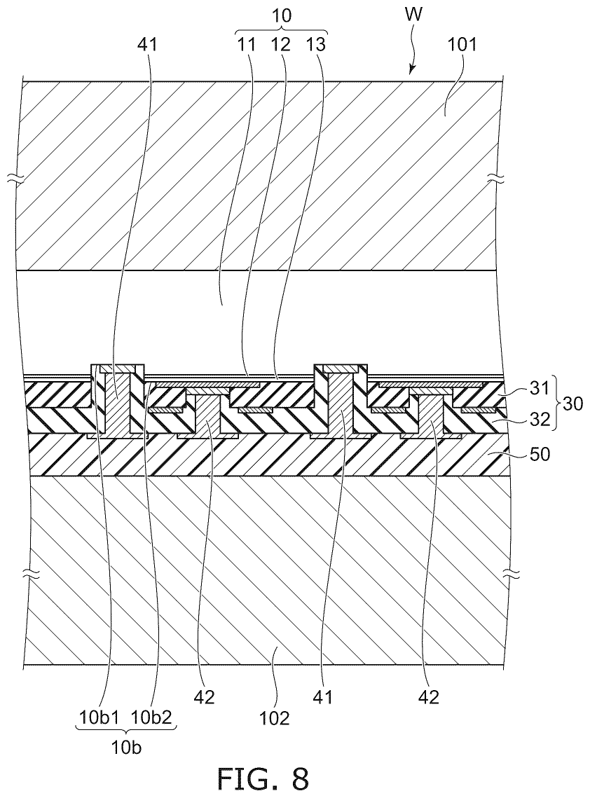

After the step of preparing the wafer W, as shown in FIG. 8, the method of manufacturing a light emitting element according to the first embodiment includes a step of bonding the second surface 10b side of the semiconductor structure body 10 to a second substrate 102 via a bonding member 50. In the illustration of FIG. 8, the vertical positions of the wafer W are inverted from the drawings up to FIG. 7.

The bonding member 50 is located between the insulating film 30 and the second substrate 102. Also, the bonding member 50 covers the first electrode 41 and the second electrode 42. The bonding member 50 is, for example, a resin member that mainly includes an epoxy resin, an acrylic resin, or a polyimide resin. For example, similarly to the first substrate 101, a substrate of sapphire, spinel, SiC, ZnS, ZnO, GaAs, Si, etc., can be used as the second substrate 102.

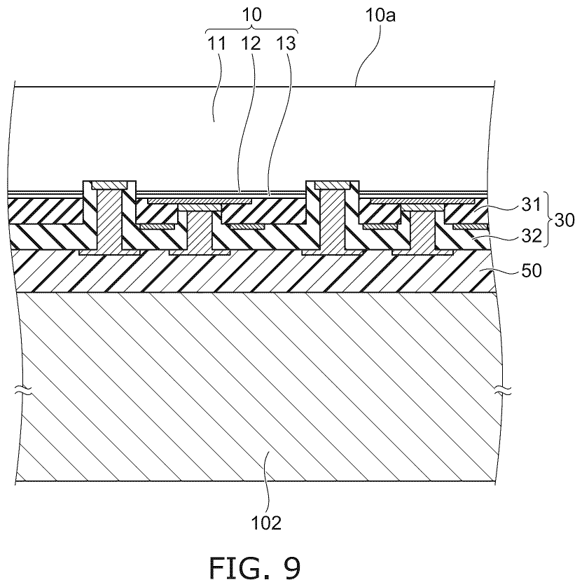

The method of manufacturing a light emitting element according to the first embodiment includes, after the step of bonding the semiconductor structure body 10 to the second substrate 102, a step of exposing the first surface 10a of the semiconductor structure body 10 as shown in FIG. 9 by separating the semiconductor structure body 10 and the first substrate 101 from each other.

For example, the first substrate 101 is removed by a method such as LLO (Laser Lift Off), grinding, polishing, etching, etc.

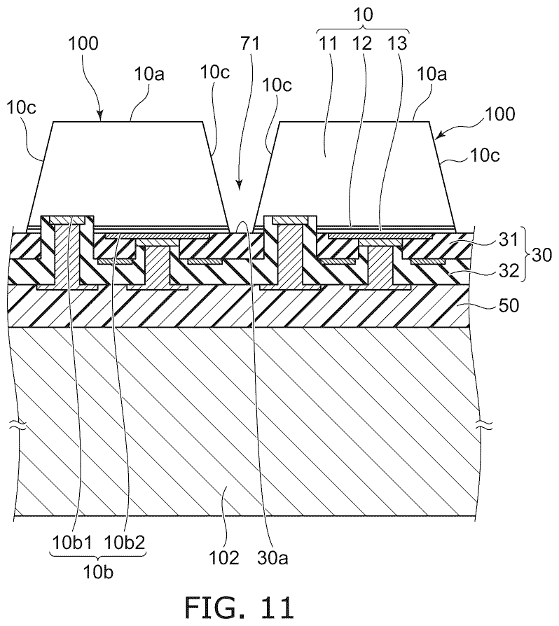

The method of manufacturing a light emitting element according to the first embodiment includes, after the step of exposing the first surface 10a of the semiconductor structure body 10, a step of forming a first groove 71 shown in FIG. 11 in the semiconductor structure body 10 by removing a portion of the semiconductor structure body 10.

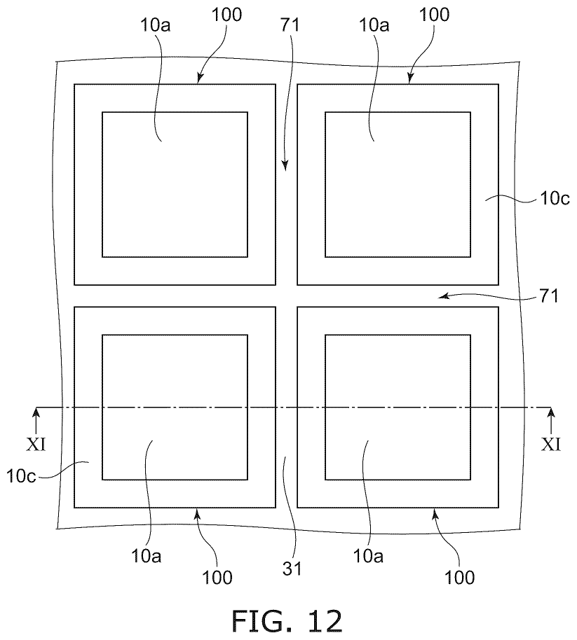

As shown in FIGS. 11 and 12, the first groove 71 separates the semiconductor structure body 10 into multiple element parts 100 on the second substrate 102. The cross section of FIG. 11 illustrates a XI-XI cross section of FIG. 12.

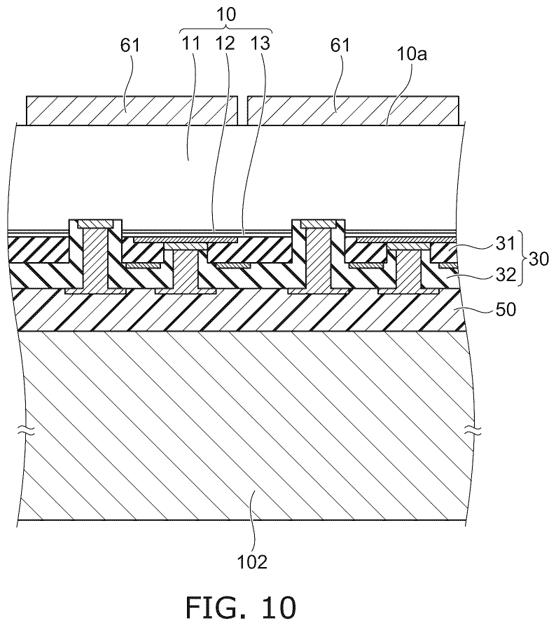

In the step of forming the first groove 71, for example, the first groove 71 is formed by removing a portion of the semiconductor structure body 10 by dry etching using a mask 61 arranged on the first surface 10a as shown in FIG. 10. The mask 61 is, for example, a resist mask. Examples of dry etching include RIE (Reactive Ion Etching). For example, a gas that includes chlorine such as Cl₂, SiCl₄, etc., can be used in the RIE. Alternatively, the first groove 71 may be formed by removing a portion of the semiconductor structure body 10 by wet etching. Compared with wet etching, the etching amount of dry etching can be easily controlled, which can facilitate stabilizing the shape of the element part 100 after etching.

The element part 100 includes the first surface 10a, the second surface 10b, and lateral surfaces 10c that connect the first surface 10a and the second surface 10b. The light that is emitted by the active layer 12 is extracted outside the semiconductor structure body 10 mainly from the first surface 10a and the lateral surfaces 10c.

In the step of forming the first groove 71 in the semiconductor structure body 10, the first groove 71 is formed to expose a portion 30a of a surface of the insulating film 30 from under the semiconductor structure body 10. The first groove 71 is defined by lateral surfaces 10c of element parts 100 and the portion 30a of the surface of the insulating film 30. As shown in FIG. 11, the lateral surface 10c is inclined with respect to the first and second surfaces 10a and 10b. The angle between the lateral surface 10c and the second surface 10b (the interior angle formed inside the semiconductor structure body 10 by the lateral surface 10c and the second surface 10b) is an acute angle, and the angle between the lateral surface 10c and the first surface 10a (the interior angle formed inside the semiconductor structure body 10 by the lateral surface 10c and the first surface 10a) is an obtuse angle. The active layer 12 is positioned at the side more proximate to the second surface 10b than the first surface 10a; therefore, when the angle between the lateral surface 10c and the second surface 10b is an acute angle and the angle between the lateral surface 10c and the first surface 10a is an obtuse angle, the active layer 12 of the element part 100 can have a large area. By forming the first groove 71 in the semiconductor structure body 10 by etching, the angle between the lateral surface 10c and the second surface 10b can be an acute angle, and the angle between the lateral surface 10c and the first surface 10a can be an obtuse angle. As shown in FIG. 11, the cross-sectional shape of the element part 100 is substantially trapezoidal.

In the step of forming the first groove 71, which separates the semiconductor structure body 10 into the multiple element parts 100, by etching, the time during which a portion of the semiconductor structure body 10 at the first surface 10a side is exposed to the etching gas or the etchant is longer than the time during which a portion of the semiconductor structure body 10 at the second surface 10b side is exposed to the etching gas or the etchant. As a result, there is a tendency for the width of the first surface 10a side of the first groove 71 to be greater than the width of the second surface 10b side. Accordingly, the cross-sectional shape of the semiconductor structure body 10 adjacent to the first groove 71 is substantially trapezoidal.

As a comparative example, when the semiconductor structure body 10 is separated into multiple element parts by forming a groove in the semiconductor structure body 10 positioned on the first substrate 101 before removing the first substrate 101, the etching of the semiconductor structure body 10 proceeds from the second surface 10b side. In such a case, the cross-sectional shape of the semiconductor structure body 10 is a substantially trapezoidal shape in which the area of the first surface 10a is greater than the area of the second surface 10b. The active layer 12 is positioned at the side that is more proximate to the second surface 10b than the first surface 10a, so that the area of the active layer 12 tends to be reduced in the case of a substantially trapezoidal shape in which the area of the first surface 10a is greater than the area of the second surface 10b.

According to the present embodiment, within the active layer 12 of the semiconductor structure body 10 that is positioned on the first substrate 101 before removing the first substrate 101, removal is performed only in the first region 10b1, on which the first electrode 41 is to be arranged. In a state in which the semiconductor structure body 10 is positioned on the first substrate 101, a groove that separates the semiconductor structure body 10 into multiple element parts has not been formed. After the semiconductor structure body 10 is bonded to the second substrate 102, the first substrate 101 is removed, and the first groove 71 is formed by causing the etching to proceed from the first surface 10a side. Thus, the cross-sectional shape of the semiconductor structure body 10 can be a substantially trapezoidal shape in which the area of the second surface 10b at the lower side is greater than the area of the first surface 10a at the upper side. Accordingly, compared to a case in which the semiconductor structure body 10 is separated into the element parts 100 on the first substrate 101, the area of the active layer 12 can be increased, and the light extraction efficiency can be increased.

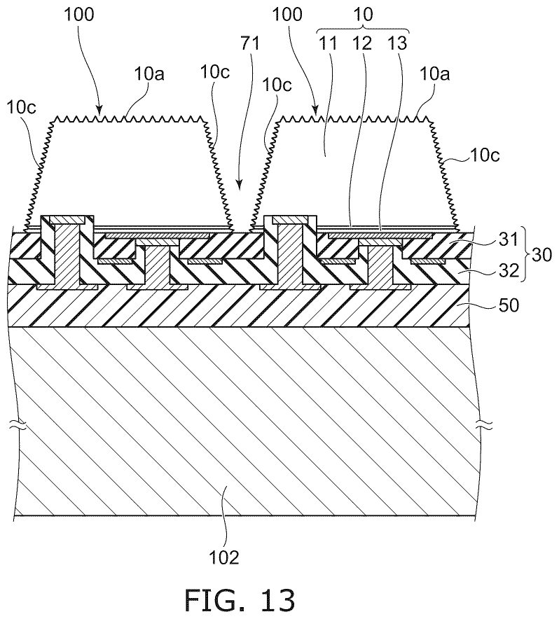

The method of manufacturing a light emitting element according to the first embodiment includes, after the step of forming the first groove 71 in the semiconductor structure body 10, the step of roughening the surfaces of the multiple element parts 100 on the second substrate 102 as shown in FIG. 13.

The first surface 10a and the lateral surfaces 10c of the element part 100 are roughened. The roughened first surface 10a and lateral surfaces 10c include multiple protrusions. By roughening the first surface 10a and the lateral surfaces 10c, the light extraction efficiency from the first surface 10a and the lateral surface 10c can be increased. For example, the first surface 10a and the lateral surface 10c are roughened by dry etching using a gas including chlorine, or wet etching using an alkaline solution such as TMAH (Tetramethylammonium hydroxide), etc. Thus, the first surface 10a and the lateral surface 10c can be roughened in a single step, so that a light emitting element with increased light extraction efficiency can be efficiently manufactured.

According to the first embodiment, the first groove 71 is formed in the semiconductor structure body 10 by removing a portion of the semiconductor structure body 10 in a state in which the semiconductor structure body 10 shown in FIG. 11 above is not roughened. Therefore, compared to when separating into the element parts 100 by removing a portion of the semiconductor structure body 10 after roughening the first surface 10a of the semiconductor structure body 10, the first surface 10a of the semiconductor structure body 10 in a highly flat state can be etched and thus the first groove 71 can be formed, which can facilitate stabilizing the shape of the element part 100.

Also, by performing the roughening step after separating into the element parts 100, the steps can be simplified, and not only the first surface 10a but also the lateral surface 10c can be roughened. As a result, the light extraction efficiency from the semiconductor structure body 10 can be increased. Also, when the semiconductor structure body 10 is grown on the C-plane of a sapphire substrate used as the first substrate 101, due to difference between the crystal orientation of the first surface 10a and that of the lateral surface 10c, the surface roughness of the first surface 10a can be greater than the surface roughness of the lateral surface 10c by performing a roughening step after separating into the element parts 100 as shown in FIG. 13. With the surface roughness of the first surface 10a greater than the surface roughness of the lateral surface 10c, the light is extracted more easily from the first surface 10a than the lateral surface 10c, so that light distribution characteristics that have high directivity in the direction directly above the first surface 10a can be obtained. For example, the surface roughness of the first surface 10a and the surface roughness of the lateral surface 10c can be expressed by the maximum height Rz. Also, for example, the surface roughness of the first surface 10a and the surface roughness of the lateral surface 10c can be expressed by the arithmetic average roughness Ra. For example, the maximum height Rz of the first surface 10a is not less than 0.5 μm and not more than 3.0 μm, and the maximum height Rz of the lateral surface 10c is not less than 10 nm and not more than 400 nm. Also, for example, the arithmetic average roughness Ra of the first surface 10a is not less than 100 nm and not more than 300 nm, and the arithmetic average roughness Ra of the lateral surface 10c is not less than 1 nm and not more than 100 nm. For example, the surface roughness of the first surface 10a and the surface roughness of the lateral surface 10c can be measured with a laser microscope, an atomic force microscope, etc.

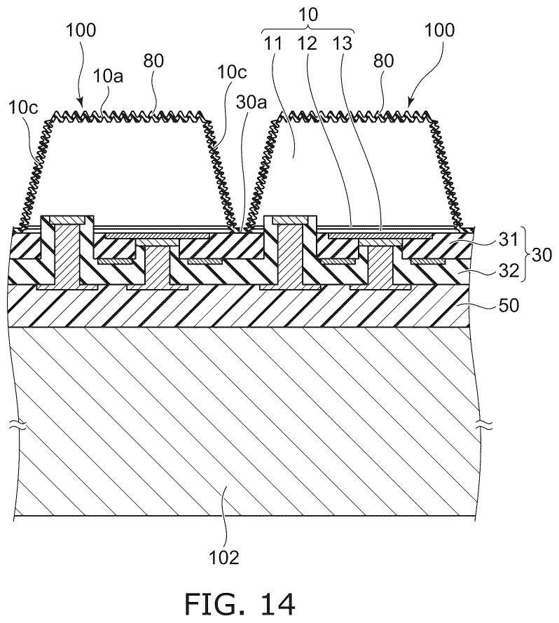

the method of manufacturing a light emitting element according to the first embodiment can include, after the step of roughening the first surface 10a and the lateral surface 10c, a step of forming a protective film 80 covering the first surface 10a and the lateral surface 10c as shown in FIG. 14. Also, the protective film 80 covers the portion 30a of the surface of the insulating film 30. For example, the protective film 80 can be formed by CVD and/or sputtering.

A shape that follows the rough surface shapes of the first surface 10a and the lateral surface 10c is formed in the surface of the protective film 80. As a result, the extraction efficiency of the light extracted from the first surface 10a and the lateral surface 10c via the protective film 80 can be increased. The protective film 80 is transmissive to the light emitted by the active layer 12. The transmittance of the protective film 80 for the light emitted by the active layer 12 is not less than 60%, and favorably not less than 70%. For example, SiO₂, SiN, and SiON can be used as the protective film 80.

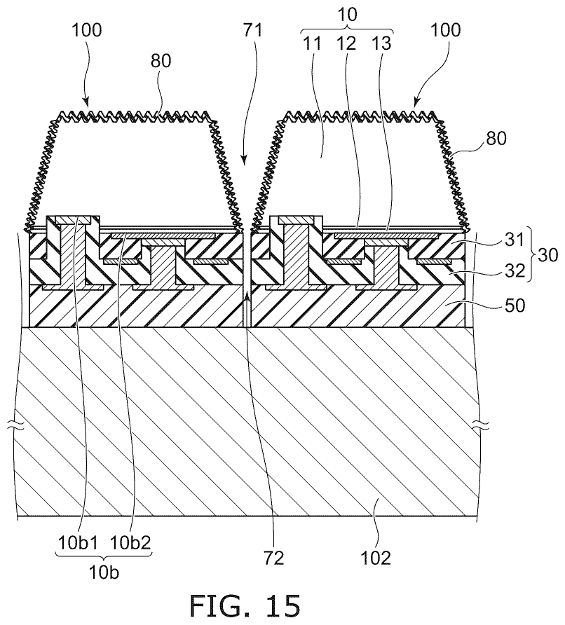

The method of manufacturing a light emitting element according to the first embodiment can further include, after the step of forming the first groove 71, a step of forming a second groove 72 in the insulating film 30 and the bonding member 50 as shown in FIG. 15 by removing a corresponding portion of the insulating film 30 and a corresponding portion of the bonding member 50 below the first groove 71.

According to the present embodiment, after the first groove 71 is formed, the first surface 10a and the lateral surface 10c are roughened; the protective film 80 is then formed; subsequently, the second groove 72 is formed. For example, the second groove 72 is formed by removing the portion of the insulating film 30 and the portion of the bonding member 50 below the first groove 71 by RIE using a mask. For example, a gas that includes fluorine such as CF₄, CHF₃, or the like is used when removing the insulating film 30, and a gas that includes oxygen such as O₂ or the like is used when removing the bonding member 50.

The second groove 72 reaches a surface of the second substrate 102. The insulating film 30 is separated by the second groove 72 into multiple portions corresponding to the multiple element parts 100. As shown in FIG. 15, in the element part 100, the end portion of the insulating film 30 and the end portion of the second surface 10b are formed to be aligned with each other. Accordingly, when the first film 31 is reflective to the light emitted by the active layer 12, the light that is emitted by the active layer 12 can be efficiently reflected. The bonding member 50 is also separated by the second groove 72 into multiple portions corresponding to the multiple element parts 100. The element parts 100 each are supported on the second substrate 102 via the bonding member 50 with the second surface 10b facing the second substrate 102.

The method of manufacturing a light emitting element according to the first embodiment includes a step of separating the second substrate 102 and the multiple element parts 100 from each other.

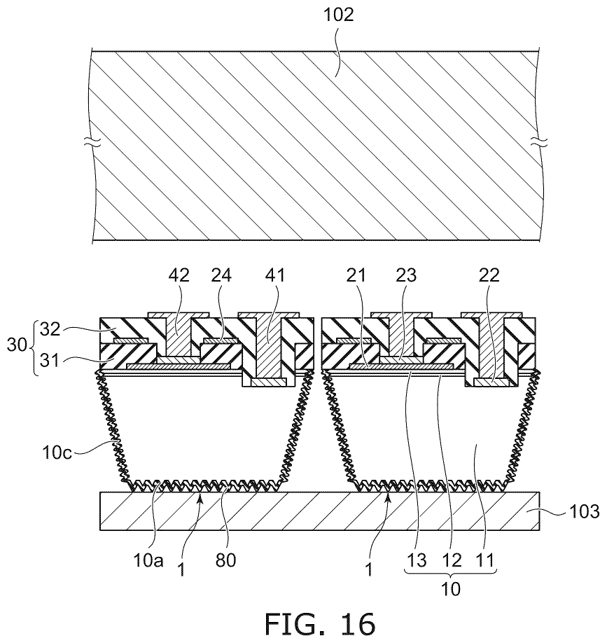

For example, the element part 100 and the second substrate 102 can be separated from each other by removing the bonding member 50 by irradiating laser light from the second substrate 102 side. As shown in FIG. 16, the first surface 10a of the element part 100 that is separated from the second substrate 102 is bonded to, for example, an adhesive support member 103 via the protective film 80. The element part 100 may be separated from the second substrate 102 after being bonded to the support member 103. After the element part 100 is separated from the second substrate 102, the first electrode 41 and the second electrode 42 are exposed by removing the remaining portion of the bonding member 50 at the insulating film 30 side by, for example, RIE. Thus, a light emitting element 1 is obtained. The exposed first and second electrodes 41 and 42 function as external connection terminals bonded to a mounting substrate. The light emitting element 1 is, for example, a light emitting diode.

### Second Embodiment

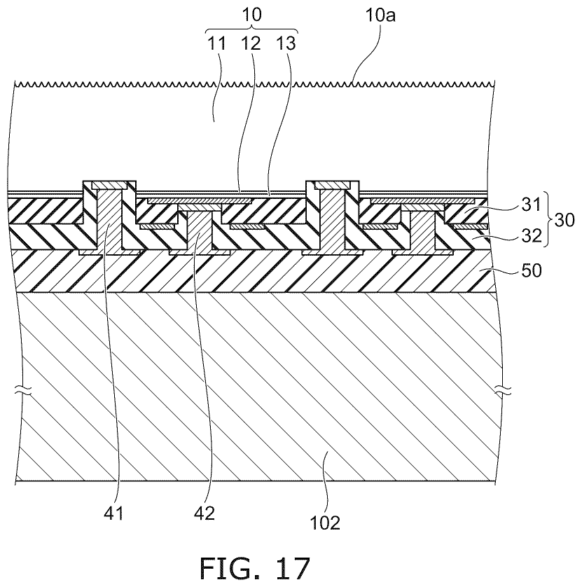

A method of manufacturing a light emitting element according to a second embodiment will be described with reference to FIGS. 17 to 19.

Similarly to the first embodiment, the method of manufacturing a light emitting element according to the second embodiment includes a step of providing the wafer W, a step of bonding the second surface 10b side of the semiconductor structure body 10 to the second substrate 102 via the bonding member 50, and a step of exposing the first surface 10a of the semiconductor structure body 10 by separating the semiconductor structure body 10 and the first substrate 101 from each other.

The method of manufacturing a light emitting element according to the second embodiment includes, after the step of exposing the first surface 10a of the semiconductor structure body 10, a step of roughening the first surface 10a of the semiconductor structure body 10 on the second substrate 102 as shown in FIG. 17.

Similarly to the first embodiment, for example, the first surface 10a is roughened by dry etching using a gas including chlorine, or by wet etching using an alkaline solution such as TMAH, etc.

The method of manufacturing a light emitting element according to the second embodiment includes, after the step of roughening the first surface 10a of the semiconductor structure body 10, a step of forming, in the semiconductor structure body 10, the first groove 71 that separates the semiconductor structure body 10 into the multiple element parts 100 on the second substrate 102 by removing a portion of the semiconductor structure body 10.

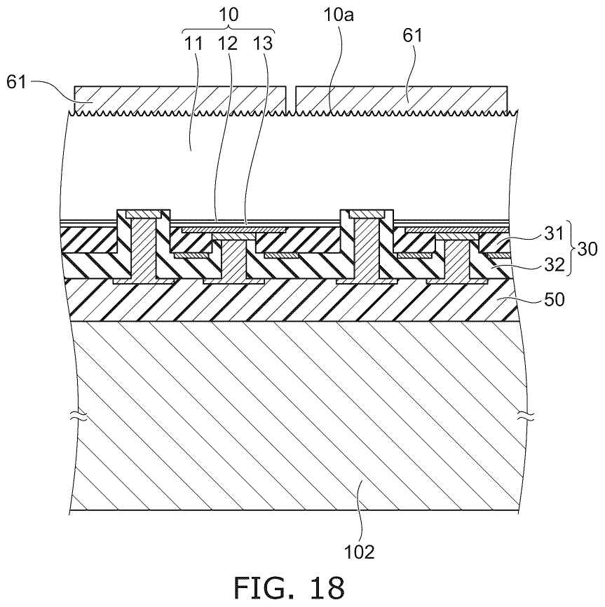

In the step of forming the first groove 71, for example, the first groove 71 is formed by removing a portion of the semiconductor structure body 10 by dry etching using the mask 61 that is shown in FIG. 18 and is located on the first surface 10a. Examples of dry etching include RIE. For example, a gas that includes chlorine such as Cl₂, SiCl₄, etc., can be used in the RIE. Because the etching controllability of dry etching is good, the shape of the element part 100 after etching is easily stabilized.

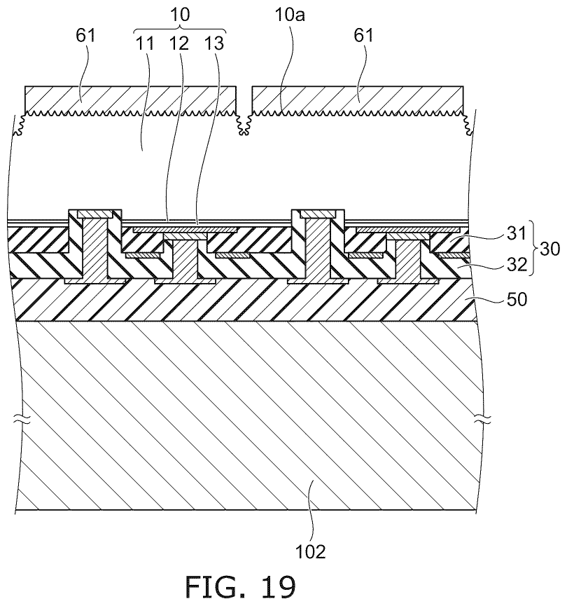

The dry etching of the semiconductor structure body 10 proceeds from the roughened first surface 10a exposed from under the mask 61. Therefore, as shown in FIG. 19, the surface roughness of the surface subjected to dry etching is greater than when the first surface 10a is pre-roughened. Accordingly, the lateral surface 10c of the element part 100 exposed in the step of forming the first groove 71 is roughened as shown in FIG. 13. As a result, the formation of the first groove 71 and the roughening of the lateral surface 10c can be performed in a single step, so that a light emitting element with increased light extraction efficiency can be efficiently manufactured. Also, when forming the first groove 71 by performing dry etching of the pre-roughened first surface 10a, the state of the surface of the lateral surface 10c is easily controlled. For example, compared to a case in which the first surface 10a and the lateral surface 10c are roughened after the first groove 71 is formed, the difference between the surface roughness of the first surface 10a and the surface roughness of the lateral surface 10c is easily reduced.

Also, the first groove 71 may be formed by removing a portion of the semiconductor structure body 10 by wet etching. Compared to dry etching, when performing wet etching, the surface roughness of the lateral surface 10c is easily increased, and the light extraction efficiency from the lateral surface 10c is easily increased.

According to the method of manufacturing a light emitting element according to the second embodiment, the light emitting element 1 is obtained by performing the step of forming the first groove 71 described above and then steps that is the same as those of the first embodiment shown in FIGS. 14 to 16 above.

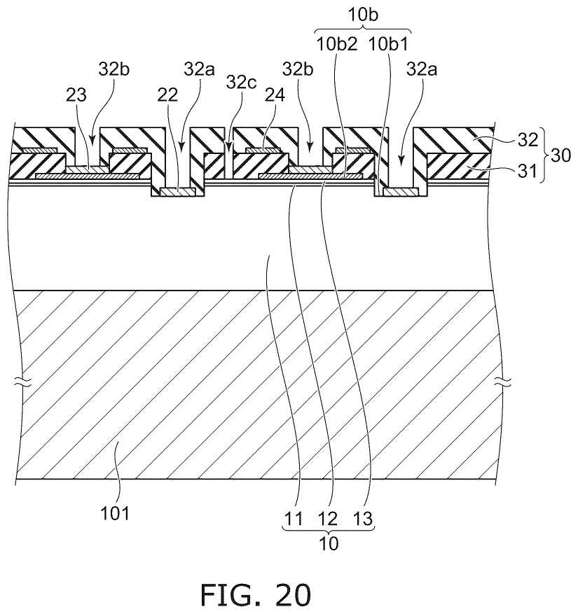

FIGS. 20 to 22 are schematic cross-sectional views for describing a first modification of the methods for manufacturing the light emitting elements according to the first and second embodiments.

According to the first modification, the step of providing the wafer W further includes forming the insulating film 30 that includes the first opening 32a, the second opening 32b, and a third opening 32c in the second surface 10b of the semiconductor structure body 10 as shown in FIG. 20. The third opening 32c extends through the second and first films 32 and 31 and reaches the second region 10b2 of the second surface 10b (the upper surface of the second semiconductor layer 13). For example, the first opening 32a, the second opening 32b, and the third opening 32c are formed simultaneously by RIE.

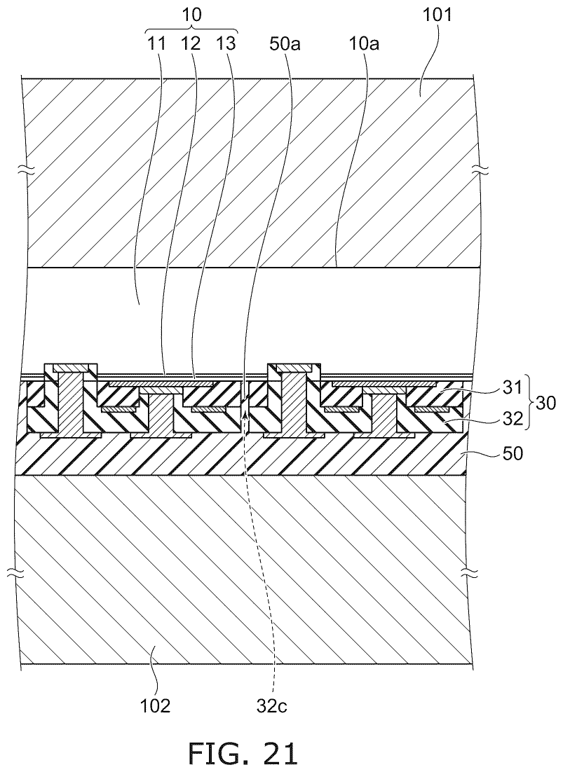

In the step of bonding the semiconductor structure body 10 to the second substrate 102 via the bonding member 50, a portion 50a of the bonding member 50 is located in the third opening 32c as shown in FIG. 21. For example, the portion 50a of the bonding member 50 is in contact with the upper surface of the second semiconductor layer 13 in the third opening 32c.

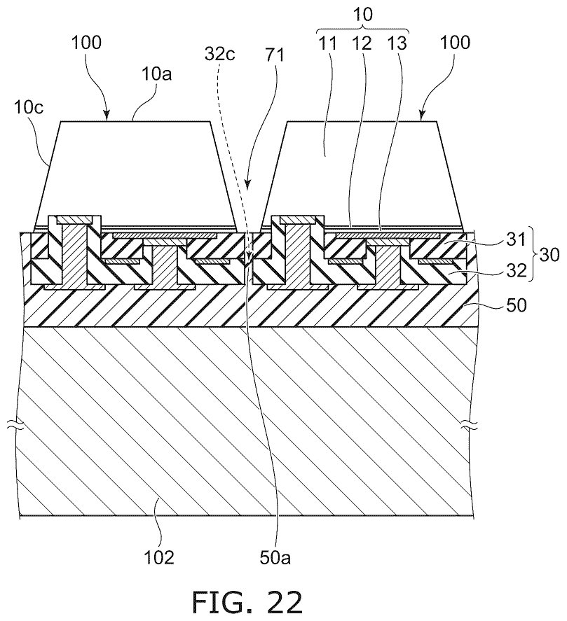

Then, in the step of forming the first groove 71, the first groove 71 is formed above the third opening 32c as shown in FIG. 22. According to the first embodiment, the first surface 10a and the lateral surface 10c of the element part 100 are roughened after the first groove 71 is formed. According to the second embodiment, as described above, the first groove 71 is formed after the first surface 10a is roughened, and thus the lateral surface 10c can be roughened in the step of forming the first groove 71.

In the step of forming the insulating film 30 according to the first modification, the insulating film 30 is divided by the third opening 32c. As described above, the third opening 32c can be formed simultaneously with the first opening 32a in which the first electrode 41 will be located and the second opening 32b in which the second electrode 42 will be disposed. The portion 50a of the bonding member 50 located in the third opening 32c can be removed when removing the bonding member 50 in the step of separating the element part 100 and the second substrate 102 from each other. As a result, as shown in FIG. 16, the multiple light emitting elements 1 that are separated from each other are obtained. Accordingly, in the first modification, the necessity of the step of forming the second groove 72 after forming the first groove 71 is eliminated, so that the light emitting element can be manufactured efficiently.

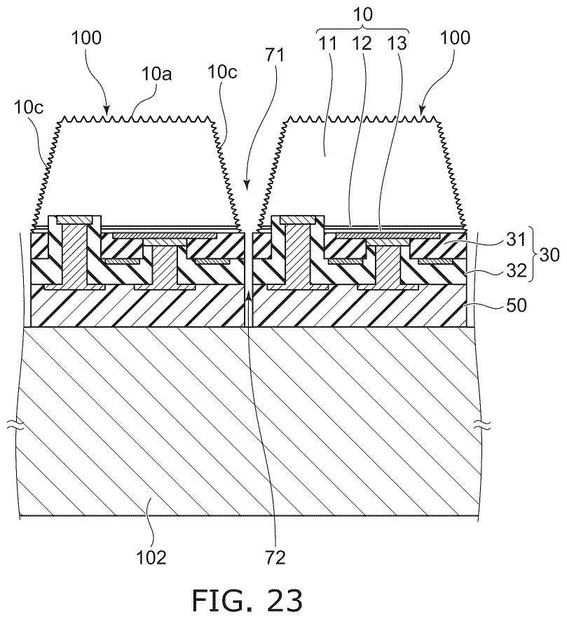

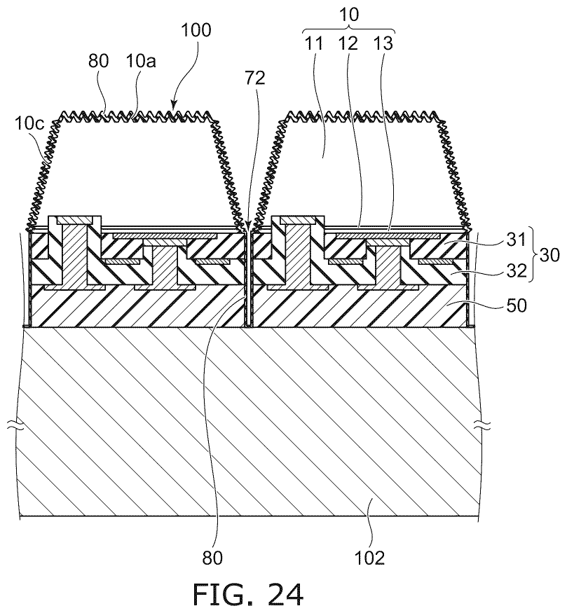

FIGS. 23 and 24 are schematic cross-sectional views for describing a second modification of the methods for manufacturing the light emitting elements according to the first and second embodiments.

In the second modification, before the step of forming the protective film 80 covering the first surface 10a and the lateral surface 10c, the second groove 72 is formed by removing a portion of the insulating film 30 and a portion of the bonding member 50 below the first groove 71 as shown in FIG. 23. In this step of forming the second groove 72, the portion of the insulating film 30 and the portion of the bonding member 50 can be removed using the semiconductor structure body 10 as a mask. Accordingly, it is unnecessary to form another mask when forming the second groove 72, so that the light emitting element can be manufactured efficiently.

The second modification further includes, after the step of forming the second groove 72, a step of forming the protective film 80 that covers the semiconductor structure body 10 and the lateral surfaces of the insulating film 30 defining the second groove 72 as shown in FIG. 24. The protective film 80 covers the first surface 10a and the lateral surfaces 10c of the element part 100. The protective film 80 also covers the lateral surfaces of the bonding member 50 defining the second groove 72. Also, the protective film 80 is located at the surface of the second substrate 102 positioned at the bottom of the second groove 72.

Subsequently, multiple light emitting elements that are separated from each other are obtained by removing the bonding member 50 in the step of separating the second substrate 102 and the element parts 100 from each other. In the light emitting elements that are obtained according to the second modification, the lateral surfaces of the insulating film 30 is covered with the protective film 80.

### Light Emitting Element

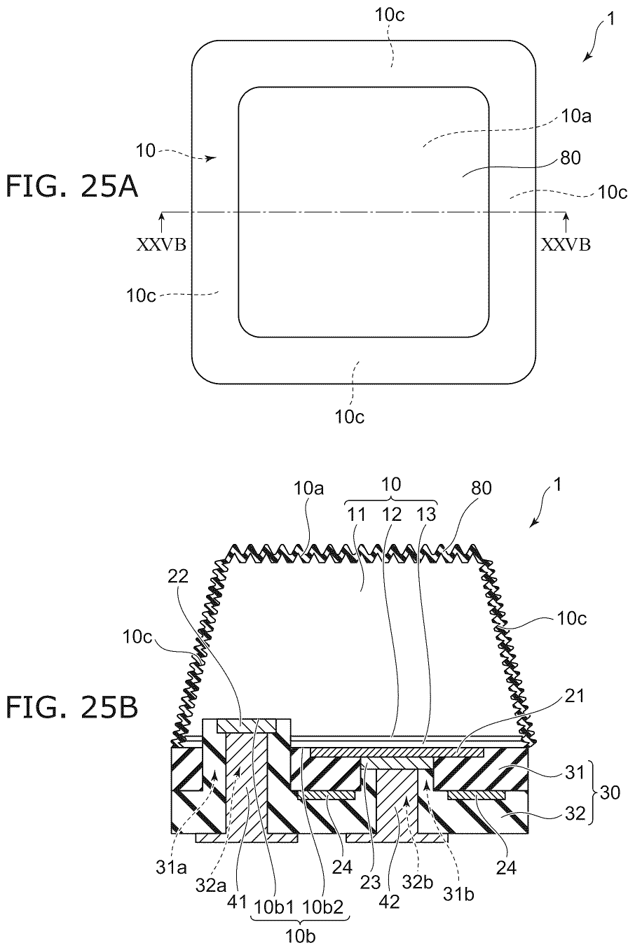

The light emitting element 1 according to an embodiment will now be described with reference to FIGS. 25A and 25B.

As described above, the light emitting element 1 includes the semiconductor structure body 10, the first electrode 41, and the second electrode 42.

The semiconductor structure body 10 includes the first semiconductor layer 11, the second semiconductor layer 13, and the active layer 12 positioned between the first semiconductor layer 11 and the second semiconductor layer 13. The semiconductor structure body 10 also includes the first surface 10a, the second surface 10b positioned at a side opposite to the first surface 10a, and the lateral surfaces 10c connecting the first surface 10a and the second surface 10b. The first surface 10a is a surface of the first semiconductor layer 11 positioned at the side opposite to the active layer 12. The second surface 10b includes the first region 10b1 in which a portion of the first semiconductor layer 11 is exposed from under the second semiconductor layer 13 and the active layer 12, and the second region 10b2 that is a surface of the second semiconductor layer 13 positioned at a side opposite to the active layer 12. The first surface 10a and the lateral surfaces 10c are rough surfaces. As shown in FIG. 25A, when viewed in plan, the shape of the semiconductor structure body 10 is quadrilateral and includes four lateral surfaces 10c. All of the four lateral surfaces 10c are rough surfaces. When the first surface 10a and the lateral surfaces 10c are rough surfaces, the light extraction efficiency from the first surface 10a and the lateral surfaces 10c can be increased.

As shown in FIG. 25B, the cross-sectional shape of the semiconductor structure body 10 is substantially trapezoidal, and the area of the second surface 10b at the lower side is greater than the area of the first surface 10a at the upper side. As a result, the area of the active layer 12 positioned more proximate to the second surface 10b than the first surface 10a can be increased, and thus the light extraction efficiency can be increased.

The surface roughness of the first surface 10a is greater than the surface roughness of the lateral surface 10c. As a result, light is extracted more easily from the first surface 10a than the lateral surface 10c, which can result in light distribution characteristics in which directivity is higher in the direction toward a location directly above the first surface 10a. As described above, for example, the surface roughness of the first surface 10a and the surface roughness of the lateral surface 10c can be expressed by the maximum height Rz. Also, for example, the surface roughness of the first surface 10a and the surface roughness of the lateral surface 10c can be expressed by the arithmetic average roughness Ra. For example, the maximum height Rz of the first surface 10a is not less than 0.5 μm and not more than 3.0 μm, and the maximum height Rz of the lateral surface 10c is not less than 10 nm and not more than 400 nm. Also, for example, the arithmetic average roughness Ra of the first surface 10a is not less than 100 nm and not more than 300 nm, and the arithmetic average roughness Ra of the lateral surface 10c is not less than 1 nm and not more than 100 nm.

The first electrode 41 is electrically connected with the first semiconductor layer 11 at the first region 10b1. The second electrode 42 is electrically connected with the second semiconductor layer 13 at the second region 10b2.

The light emitting element 1 can further include the first conductive film 21, the second conductive film 22, the third conductive film 23, the reflective film 24, the insulating film 30, and the protective film 80 described above.

Hereinabove, embodiments of the invention are described with reference to specific examples. However, the invention is not limited to these specific examples. All configurations practicable by an appropriate design modification by one skilled in the art based on the embodiments of the invention described above also are within the scope of the invention to the extent that the purport of the invention is included. Furthermore, various modifications and alterations within the spirit of the invention will be readily apparent to those skilled in the art, and all such modifications and alterations also are within the scope of the invention.

What is claimed is:

1. A method of manufacturing a light emitting element, comprising:
providing a wafer, the wafer comprising:
a first substrate,
a semiconductor structure body located on the first substrate, the semiconductor structure body having a first surface at a first substrate side, and a second surface at a side opposite the first surface, the semiconductor structure body comprising:
a first semiconductor layer,
a second semiconductor layer located farther from the first substrate than the first semiconductor layer is from the first substrate, and
an active layer positioned between the first semiconductor layer and the second semiconductor layer,
a first electrode located on the second surface of the semiconductor structure body, the first electrode being electrically connected with the first semiconductor layer, and
a second electrode located on the second surface of the semiconductor structure body, the second electrode being electrically connected with the second semiconductor layer;
bonding a second surface side of the semiconductor structure body to a second substrate via a bonding member;
after the bonding of the semiconductor structure body to the second substrate, exposing the first surface of the semiconductor structure body by separating the semiconductor structure body and the first substrate from each other;
after the exposing of the first surface of the semiconductor structure body, forming a first groove in the semiconductor structure body by removing a portion of the semiconductor structure body, the first groove separating the semiconductor structure body into a plurality of element parts on the second substrate;
after the forming of the first groove in the semiconductor structure body, roughening surfaces of the plurality of element parts on the second substrate; and
separating the second substrate and the plurality of element parts from each other.

2. A method of manufacturing a light emitting element, comprising:
providing a wafer, the wafer comprising:
a first substrate,
a semiconductor structure body located on the first substrate, the semiconductor structure body having a first surface at a first substrate side, and a second surface at a side opposite the first surface, the semiconductor structure body comprising:
a first semiconductor layer,
a second semiconductor layer located farther from the first substrate than the first semiconductor layer is from the first substrate, and
an active layer positioned between the first semiconductor layer and the second semiconductor layer,
a first electrode located on the second surface of the semiconductor structure body, the first electrode being electrically connected with the first semiconductor layer, and
a second electrode located on the second surface of the semiconductor structure body, the second electrode being electrically connected with the second semiconductor layer;
bonding a second surface side of the semiconductor structure body to a second substrate via a bonding member;
after the bonding of the semiconductor structure body to the second substrate, exposing the first surface of the semiconductor structure body by separating the semiconductor structure body and the first substrate from each other;
after the exposing of the first surface of the semiconductor structure body, roughening the first surface of the semiconductor structure body while the semiconductor structure body is on the second substrate;
after the roughening of the first surface of the semiconductor structure body, forming a first groove in the semiconductor structure body by removing a portion of the semiconductor structure body, the first groove separating the semiconductor structure body into a plurality of element parts on the second substrate; and
separating the second substrate and the plurality of element parts from each other.

3. The method of manufacturing a light emitting element according to claim 2, wherein:
in the forming of the first groove in the semiconductor structure body, the first groove is formed in the semiconductor structure body by removing the portion of the semiconductor structure body from the roughened first surface side by dry etching.

4. The method of manufacturing a light emitting element according to claim 1, wherein:
the providing of the wafer further comprises forming an insulating film at the second surface of the semiconductor structure body, and
in the forming of the first groove in the semiconductor structure body, the first groove is formed to expose the insulating film from under the semiconductor structure body.

5. The method of manufacturing a light emitting element according to claim 2, wherein:
the providing of the wafer further comprises forming an insulating film at the second surface of the semiconductor structure body, and
in the forming of the first groove in the semiconductor structure body, the first groove is formed to expose the insulating film from under the semiconductor structure body.

6. The method of manufacturing a light emitting element according to claim 3, wherein:
the providing of the wafer further comprises forming an insulating film at the second surface of the semiconductor structure body, and
in the forming of the first groove in the semiconductor structure body, the first groove is formed to expose the insulating film from under the semiconductor structure body.

7. The method of manufacturing a light emitting element according to claim 4, further comprising:
after the forming of the first groove, forming a second groove in the insulating film and in the bonding member by removing a portion of the insulating film and a portion of the bonding member that are located below the first groove.

8. The method of manufacturing a light emitting element according to claim 5, further comprising:
after the forming of the first groove, forming a second groove in the insulating film and in the bonding member by removing a portion of the insulating film and a portion of the bonding member that are located below the first groove.

9. The method of manufacturing a light emitting element according to claim 6, further comprising:
after the forming of the first groove, forming a second groove in the insulating film and in the bonding member by removing a portion of the insulating film and a portion of the bonding member that are located below the first groove.

10. The method of manufacturing a light emitting element according to claim 1, wherein:
the providing of the wafer further comprises forming an insulating film on the second surface of the semiconductor structure body,
the insulating film includes a first opening, a second opening, and a third opening,
in the providing of the wafer, the first electrode is disposed in the first opening, and the second electrode is disposed in the second opening, and
in the forming of the first groove, the first groove is formed above the third opening.

11. The method of manufacturing a light emitting element according to claim 2, wherein:
the providing of the wafer further comprises forming an insulating film on the second surface of the semiconductor structure body,
the insulating film includes a first opening, a second opening, and a third opening,
in the providing of the wafer, the first electrode is disposed in the first opening, and the second electrode is disposed in the second opening, and
in the forming of the first groove, the first groove is formed above the third opening.

12. The method of manufacturing a light emitting element according to claim 3, wherein:
the providing of the wafer further comprises forming an insulating film on the second surface of the semiconductor structure body,
the insulating film includes a first opening, a second opening, and a third opening,
in the providing of the wafer, the first electrode is disposed in the first opening, and the second electrode is disposed in the second opening, and
in the forming of the first groove, the first groove is formed above the third opening.

13. The method of manufacturing a light emitting element according to claim 7, wherein:
in the forming of the second groove, the portion of the insulating film and the portion of the bonding member are removed by using the semiconductor structure body as a mask.

14. The method of manufacturing a light emitting element according to claim 8, wherein:
in the forming of the second groove, the portion of the insulating film and the portion of the bonding member are removed by using the semiconductor structure body as a mask.

15. The method of manufacturing a light emitting element according to claim 9, wherein:
in the forming of the second groove, the portion of the insulating film and the portion of the bonding member are removed by using the semiconductor structure body as a mask.

16. The method of manufacturing a light emitting element according to claim 13, further comprising:
forming a protective film after the forming of the second groove,
the protective film covering the semiconductor structure body, and a lateral surface of the insulating film defining the second groove.

17. The method of manufacturing a light emitting element according to claim 14, further comprising:
forming a protective film after the forming of the second groove,
the protective film covering
the semiconductor structure body, and
a lateral surface of the insulating film defining the second groove.

18. The method of manufacturing a light emitting element according to claim 15, further comprising:
forming a protective film after the forming of the second groove,
the protective film covering
the semiconductor structure body, and
a lateral surface of the insulating film defining the second groove.

19. A light emitting element, comprising:
a semiconductor structure body comprising:
a first semiconductor layer,
a second semiconductor layer,
an active layer positioned between the first semiconductor layer and the second semiconductor layer,
a first surface, the first surface being a surface of the first semiconductor layer positioned at a side opposite to the active layer,
a second surface positioned at a side opposite to the first surface,
a lateral surface connecting the first surface and the second surface, the second surface including:
a first region in which a portion of the first semiconductor layer is exposed from under the second semiconductor layer and the active layer, and
a second region being a surface of the second semiconductor layer positioned at a side opposite to the active layer;
a first electrode electrically connected with the first semiconductor layer at the first region; and
a second electrode electrically connected with the second semiconductor layer at the second region, wherein:
the first surface and the lateral surface are roughened surfaces, and
an area of the second surface is greater than an area of the first surface.

20. The light emitting element according to claim 19, wherein:
a surface roughness of the first surface is greater than a surface roughness of the lateral surface.
